(19) United States
(12) Patent Application Publication
(10) Pub. No.: US 2026/0013080 A1
(43) Pub. Date: Jan. 8, 2026

(54) INVERTIBLE TWO-PHASE MODULE COOLING APPARATUS AND METHOD

(71) Applicant: Samtec, Inc., New Albany, IN (US)

(72) Inventor: Thomas A. Hall, III, New Albany, IN (US)

(21) Appl. No.: 18/992,523

(22) PCT Filed: Jun. 30, 2023
(86) PCT No.: PCT/US2023/026762

§ 371 Date: Jan. 8, 2025

Related U.S. Application Data
(60) Provisional application No. 63/359,387, filed on Jul. 8, 2022.

(51) Int. Cl. H05K 7/20; B33Y 80/00

(52) U.S. Cl. CPC H05K 7/2039; B33Y 80/00

(57) ABSTRACT

A heat sink apparatus and method for heat transfer. The heat sink may include one or more fins. The heat sink may include one or more cavities. The heat sink may include one or more working fluids. The heat sink, or portions thereof, may be made by additive manufacturing.

### TECHNICAL FIELD

The present embodiments relate generally to a heat sink.

### BACKGROUND

Typical heat sinks may include solid fins, thereby increasing thermal resistance and a longer thermal path. Thus, there is a need to shorten the thermal path and/or reduce thermal resistance of the heat sink.

The present invention is directed at overcoming, or at least improving upon, the disadvantages of the prior art.

### BRIEF DESCRIPTION OF OTHER TECHNICAL FEATURES

U.S. Pat. Nos. 11,089,716; 10,534,145 and US Patent Publication No. 2016/0218455 are hereby incorporated by reference in their entireties.

### SUMMARY

In some embodiments of the invention, for example, a heat sink may include a body that defines at least one hollow portion. In various embodiments, the heat sink may include a fluid in at least one hollow portion.

In addition, in various embodiments, the fluid may be air. In some embodiments, the fluid may be a liquid other than air. In various embodiments, the fluid may be a combination of air and a liquid other than air. In some embodiments, at least one hollow portion may be fluidly sealed from environmental air. In various embodiments, the body may be made by additive manufacturing such as printing. In some embodiments, the body may not be die cast. In various embodiments, the body may not be made by a progressive die. Moreover, in some embodiments, a first side of the body may define a fin and at least one hollow portion is defined by a first interior wall of the fin. In various embodiments, the body may be made from or contains a thermally conductive material, such as a metal.

In some embodiments, a device may include one or more heat sinks having one or more fins. In various embodiments, the device may include one or more hollow portions within one or more fins.

In addition, in various embodiments, the one or more heat sinks may operate in a first orientation and a second orientation different from the first orientation. In some embodiments, the one or more hollow portions may include one or more working fluids therein. In various embodiments, the one or more heat sinks may include one or more members. In some embodiments, the one or more heat sinks may be made by additive manufacturing. Moreover, in various embodiments, one or more heat sinks may be made by at least powder bed fusion. In some embodiments, the one or more hollow portions may be fluidly sealed from environmental air. In various embodiments, one or more hollow portions and/or one or more fins may taper in a direction away from one or more heat sources of the device. In some embodiments, the one or more heat sinks may include one or more chambers for at least one of a thermal interface pad, a first integrated circuit, a printed circuit board, and/or a second integrated circuit.

These and other advantages and features, which characterize the embodiments, are set forth in the claims annexed hereto and form a further part hereof. However, for a better understanding of the embodiments, and of the advantages and objectives attained through its use, reference should be made to the drawings and to the accompanying descriptive matter, in which there are described example embodiments. This summary is merely provided to introduce a selection of concepts that are further described below in the detailed description, and is not intended to identify key or essential features of the claimed subject matter, nor is it intended to be used to limit the scope of the claimed subject matter, nor to define the field of endeavor.

### BRIEF DESCRIPTION OF THE ILLUSTRATIONS

In the drawings, like reference characters generally refer to the same parts throughout the different views. Also, the drawings are not necessarily to scale, emphasis instead generally being placed upon illustrating the principles of the invention.

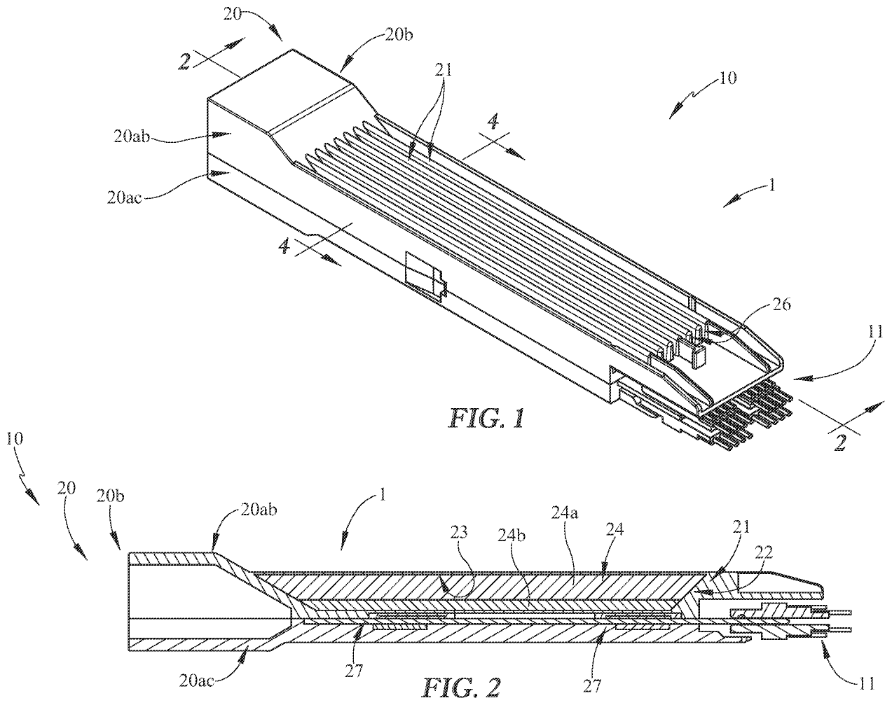

FIG. 1 is a rear perspective view of one embodiment of a heat sink within a module application.

FIG. 2 is a side sectional view of FIG. 1 taken along line 2-2.

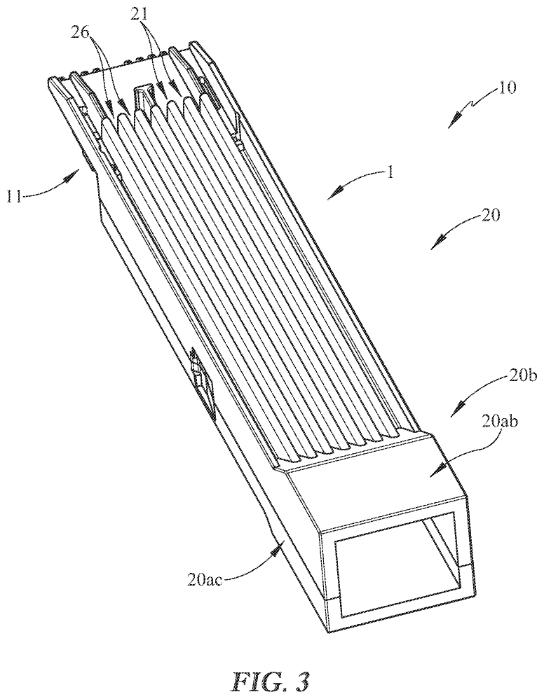

FIG. 3 is a front perspective view of the heat sink within the module application of FIG. 1.

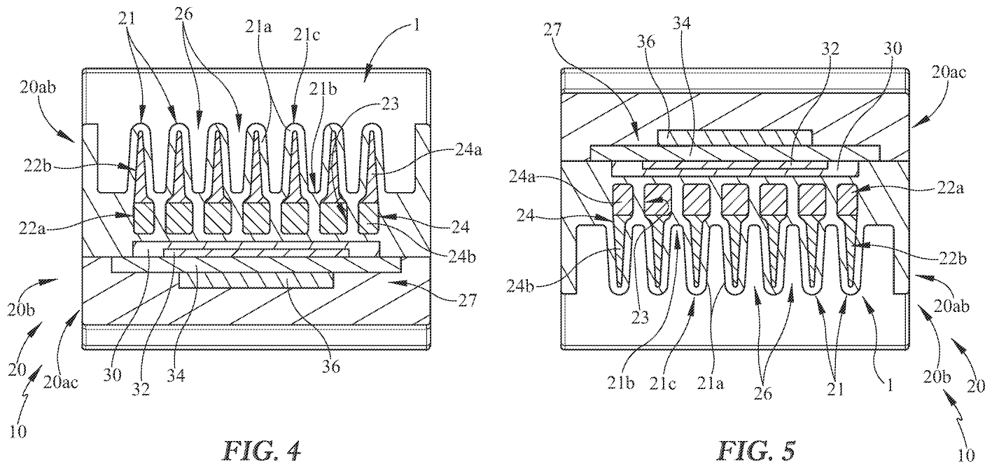

FIG. 4 is a sectional view of the heat sink of FIG. 1 taken along line 4-4 illustrating the heat sink in an upright or first orientation.

FIG. 5 is a sectional view of the heat sink of FIG. 1 taken along line 4-4 illustrating the heat sink in an inverted or second orientation.

### DETAILED DESCRIPTION

Embodiments may further be understood with reference to the various Figures. With reference to Figures, an embodiment provides one or more heat sinks 20 having two-phase cooling to transfer heat from one or more heat producing devices/structures. The one or more heat sinks 20 may include a body 20a. The heat sink 20 or body 20a includes or defines one or more fins 21 projecting outwardly therefrom. The one or more heat sinks 20 (e.g. body 20a, upper shell 20ab) and/or fins 21 include one or more hollow portions/cavities/voids 22 therein. The one or more cavities 22 may include one or more working fluids 24 therein. As shown in a first orientation in FIGS. 1-4, the working fluid 24 may be vaporized at the base/first/bottom portion 22a of the cavity 22 and subsequently rise upwardly or move towards a second/top portion 22b of the one or more cavities 22/fins 21. The vapor then condenses against an interior periphery 23 or top portion 22b of the one or more cavities 22 transferring heat thorough the fins 21 (e.g. walls) to one or more air channels 26 between/defining the fins 21. The condensate then returns or flows down (e.g. gravity) towards the base or bottom portion 22a of the cavity.

The one or more heat sinks 20, or portions thereof, may be used in a variety of applications or devices to transfer heat. For example, the one or more applications/devices may include, but is not limited to, one or more modules 10, a server rack, optical to electrical connectors, electrical connector 11, etc.

In some implementations, the heat sink 20 or body 20a may be defined by one or more members/pieces. As shown in the one embodiment of the Figures, the heat sink 20 or body 20a may include an upper/first shell or member 20ab and a lower/second shell or member 20ac. The heat sink 20, or portions thereof (e.g. upper shell 20ab), may define or include the one or more cavities 22 and/or one or more fins 21. In the one embodiment shown in the Figures, the body 20a or upper shell 20ab may include the one or more cavities 22 and the one or more fins 21. The heat sink 20, body 20a, upper shell 20ab, and/or lower shell 20ac may include or define one or more chambers 27 for positioning one or more devices (e.g. heat generating devices or heat sources, printed circuit boards, thermal interfaces, integrated circuits, etc.). As shown in FIGS. 2, 4, and 5, the chamber 27, if used, may include or position a thermal interface pad 30, a first integrated circuit 32 (e.g. heat source), a printed circuit board 34, and/or a second integrated circuit 36 (e.g. heat source). In the one embodiment shown in the Figures, the one or more chambers 27 is defined by both the upper shell 20ab and the lower shell 20ac. Although the heat sink 20 or body 20a is shown as two combined members (e.g. upper shell, lower shell), it should be understood that the heat sink 20 may be a single member in some embodiments. Further, in some embodiments, the heat sink may be a fully contained separate unit from the module with a separable thermal interface surface to the module.

In some implementations, the one or more cavities 22 may be positioned within one or more fins 21 of the heat sink 20 (e.g. body, upper shell). The cavity 22 may include or define an interior periphery 23 or wall 21a of the one or more fins 21 within the body 20a or upper shell 20ab. The fins 21 project into the air channel to define the one or more air channels adjacent the fins 21 or heat sink 20. The fin(s) 21 and/or one or more cavities 22 may taper or narrow in width in the direction away from the heat source (e.g. integrated circuits), chamber 27, and/or remaining portion of the body 20a. As shown in FIG. 4, the fins 21 may taper from a proximal end 21b towards the distal/free end 21c. Also shown in FIG. 4, the cavity 22 may taper from the bottom portion 22a towards the top portion 22b. The air channel 26 between adjacent fins 21 may increase in size (e.g. width) towards the distal or free end 21c of the fin 21. In some embodiments, a portion of the bottom portion 22a of the cavity 22 or interior wall 23 may not taper and be positioned outside the fin 21 within the body or upper shell. The top portion 22b of the cavity 22 or interior wall 23 may taper in a portion of the heat sink body 20a and through the fin 21, from the proximal end 21b to the distal/free end 21c. The one or more cavities 22 and the working fluid 24 therein may be fluidly sealed from environmental air 1. In some embodiments, the heat sink may include one or more tap or through holes (not shown) positioned or extending into the one or more cavities 22. The through holes, if used, may be sealed after working fluid 24 is inserted/pressurized into the cavities 22. One or more set screw (not shown), if used, may be used to releasably access/seal the through hole(s). In some implementations, the working fluid 24 may be air 24a, a liquid 24b (e.g. Novec 649, different from air), or combinations thereof. It should be understood that the one or more working fluids may be a variety of materials/fluids and still be within the scope of the invention.

The heat sink 20, or portions thereof, may be of a variety of shapes, profiles, sizes, lengths, quantities, constructions, and materials. The one or more materials may be of any metallic or thermally conductive material. For example, aluminum, zinc, and/or copper (e.g. alloy) may be used in some implementations.

In some implementations, the heat sink 20 or body 20a may be made by additive manufacturing. For example, in some embodiments, the heat sink 20 (e.g. body) may be printed with one or more materials. One such process may be, but is not limited to, a powder bed fusion process. Two or more members of the heat sink 20 or body 20a (e.g. printed members) may be combined together for assembly. In the one embodiment shown in the Figures, a printed lower shell 20ac and a printed upper shell 20ab may be combined in a variety of methods and still be within the scope of the invention. For example, the two members or shells 20ab and 20ac may be welded together to define the heat sink body 20a or chamber 27. Alternatively, a single body may be printed. In some embodiments, the heat sink or body may be printed with or without the components (e.g. heat generating devices or heat sources, printed circuit boards, thermal interfaces, integrated circuits, etc.) within the one or more chambers 27. The process to manufacture the one or more heat sinks, or portions thereof (e.g. body), may be described as not being made by or from a die cast and/or a progressive die.

In some implementations, the heat sink 20, or portions thereof, may be positioned in one or more orientations in a variety of applications. In one or more orientations, the heat sink 20 may transfer heat in a variety of methods/ways. Different orientations may also have a similar or different heat transfer performance. Although the heat transfer may be similar between two orientations, two orientations may have different methods of heat transfer as shown in FIGS. 4 and 5. As shown in FIG. 4, the heat sink 20 or module 10 may be in a first or upright orientation. In the first orientation, the heat sink 20 may include at least two-phase heat transfer and forced convection heat transfer. When upright, the heat travels from the heat source (e.g. integrated circuits 32, 36) through the thermal interface material or pad 30 and the heat sink material/wall between or adjacent the base 22a of the one or more cavities 22. As the working fluid 24 heats, the fluid 24b may boil at a target set point (e.g. Novec 649 boils at 49 degrees C. at 1 atm). The vapor then condenses on the inside of the wall or interior periphery 23 again at 49 degrees C. at 1 atm, transferring the heat through the one or more fin walls 21a and to the one or more air channels 26. The condensate then flows back (e.g. by gravity) to the remaining fluid 24b or towards the base and is recycled in the process. In some embodiments, the boiling point of the fluid may increase as the chamber pressure increases. As shown in FIG. 5, the heat sink 20 or module 10 may be in a second or inverted orientation, different from the first orientation. In the second orientation, the heat sink 20 may include at least conductive heat transfer and forced convection heat transfer. As show in FIG. 5 when the heat sink 20 is in a second or inverted orientation, the fluid 24b may not come in contact with the heat sink material/wall between or adjacent the base 22a of the one or more cavities 22. As such, two-phase heat transfer may not occur. However, heat may be transferred through the heat sink 20, fin wall 21a and/or upper shell 20ab to the one or more air channels 26, to provide cooling.

In one implementation as shown in Table 1 below, the heat transfer rate through the one or more fins or heat sink may be increased. The following Table 1 provides the value, description, and formulas for several characteristics of the one embodiment of the heat sink 20, or portions thereof, in the first orientation shown in FIGS. 1-4.

TABLE 1

| Desc | Var | Val | Unit | Formula |
|---|---|---|---|---|
| Al 3003 conductivity | k | 163 | W/m K | |
| Boliling Point of Novec 649 | T1 | 49 | C. | |
| Ambient in the Box | T2 | 45 | C. | |
| Fin Wall Thickness | L | 500.0E−6 | m | |
| heat flux | q | 1.3E+6 | w/m\hat{ }2 | q = −k*(T1 − T2)/L |
| heat transfer coeff | h | 326.0E+3 | w/m\hat{ }2 K | h = q/(T2 − T1) |
| Fin Internal Area | A | 5240 | mm\hat{ }2 | |
| | A | 5.2E−3 | m\hat{ }2 | |
| heat transfer rate | Q | 6.8E+3 | w | Q = h*A*(T1 − T2) |
| Thermal Resistance | R | 585.4E−6 | K/w | R = (T1 − T2)/Q |
| | | | zzzzzzzz | |

While several embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings is/are used. Those skilled in the art will recognize, or be able to ascertain using no more than routine experimentation, many equivalents to the specific embodiments described herein. It is, therefore, to be understood that the foregoing embodiments are presented by way of example only and that, within the scope of the appended claims and equivalents thereto, embodiments may be practiced otherwise than as specifically described and claimed. Embodiments of the present disclosure are directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present disclosure.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

It is to be understood that the embodiments are not limited in its application to the details of construction and the arrangement of components set forth in the description or illustrated in the drawings. The invention is capable of other embodiments and of being practiced or of being carried out in various ways. Unless limited otherwise, the terms “connected,” “coupled,” “in communication with,” and “mounted,” and variations thereof herein are used broadly and encompass direct and indirect connections, couplings, and mountings. In addition, the terms “connected” and “coupled” and variations thereof are not restricted to physical or mechanical connections or couplings.

The foregoing description of several embodiments of the invention has been presented for purposes of illustration. It is not intended to be exhaustive or to limit the invention to the precise steps and/or forms disclosed, and obviously many modifications and variations are possible in light of the above teaching.

1. A heat sink comprising:
a body that defines at least one hollow portion; and
a fluid in the at least one hollow portion.

2. The heat sink of claim 1 wherein the fluid is air.

3. The heat sink of claim 1 wherein the fluid is a liquid other than air.

4. The heat sink of claim 1 wherein the fluid is a combination of air and a liquid other than air.

5. The heat sink of claim 1 wherein the at least one hollow portion is fluidly sealed from environmental air.

6. The heat sink of claim 1 wherein the body is made by additive manufacturing such as printing.

7. The heat sink of claim 1 wherein the body is not die cast.

8. The heat sink of claim 1 wherein the body is not made by a progressive die.

9. The heat sink of claim 1 wherein a first side of the body defines a fin and the at least one hollow portion is defined by a first interior wall of the fin.

10. The heat sink of claim 1 wherein the body is made from or contains a thermally conductive material, such as a metal.

11. A device comprising:
one or more heat sinks having one or more fins and one or more hollow portions within the one or more fins.

12. The device of claim 11 wherein the one or more heat sinks operate in a first orientation and a second orientation different from the first orientation.

13. The device of claim 11 wherein the one or more hollow portions includes one or more working fluids therein.

14. The device of claim 11 wherein the one or more heat sinks includes one or more members.

15. The device of claim 11 wherein the one or more heat sinks is made by additive manufacturing.

16. The device of claim 11 wherein the one or more heat sinks is made by at least powder bed fusion.

17. The device of claim 11 wherein the one or more hollow portions is fluidly sealed from environmental air.

18. The device of claim 11 wherein at least one of the one or more hollow portions and the one or more fins taper in a direction away from one or more heat sources of the device.

19. The device of claim 11 wherein the one or more heat sinks include one or more chambers for at least one of a thermal interface pad, a first integrated circuit, a printed circuit board, and/or a second integrated circuit.
